(19) United States
(12) Patent Application Publication
(10) Pub. No.: US 2005/0205917 A1
(43) Pub. Date: Sep. 22, 2005

(54) Trench capacitor having an insulation collar and corresponding fabrication method

(75) Inventor: Harald Seidl, Feldkirchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/071,536

(22) Filed: Mar. 4, 2005

(30) Foreign Application Priority Data
Mar. 16, 2004 (DE) 10 2004 012 855.3

(51) Int. Cl. H01L 27/108; H01L 21/8242

(52) U.S. Cl. 257/301; 438/243; 438/386; 257/304

(57) ABSTRACT

The present invention provides a trench capacitor, in particular for use in a semiconductor memory cell, having a trench (5) formed in a semiconductor substrate (1); an insulation collar (3) in the upper region of the trench (5); a first conductive capacitor electrode (1a) situated in the trench (5) or in the semiconductor substrate (1); a conductive second capacitor electrode (10, 25, 30), situated in the trench (5), has a lower nonmetallic part (10) and an upper metallic part (30), the upper metallic part (30) extending right into the region between the insulation collar (3); a dielectric layer (4) as capacitor dielectric situated between the first and second capacitor electrodes (1a; 10, 25, 30). A part (25) made of a metal silicide is situated between the lower nonmetallic part (10) and the upper metallic part (30). The invention likewise provides a corresponding fabrication method.

### CLAIM FOR PRIORITY

This application claims priority to German Application No. 10 2004 012 855.3 filed Mar. 16, 2004, which is incorporated herein, in its entirety, by reference.

The present invention relates to a trench capacitor, in particular for use in a semiconductor memory cell, and a corresponding fabrication method, in accordance with the preamble of claim 1, as disclosed in DE 10 128 718 A1.

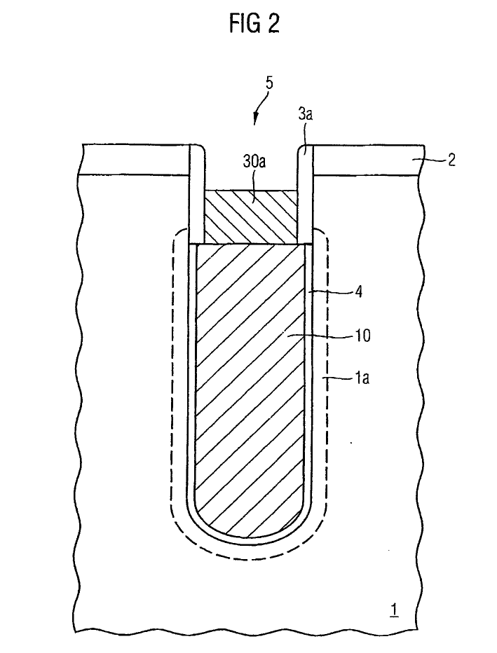

FIG. 2 shows a trench capacitor disclosed in DE 101 28 718 A1.

In FIG. 2, reference symbol 1 designates a silicon semiconductor substrate. Reference symbol 2 designates a pad nitride layer, under which a pad oxide layer (not shown) is situated. A trench 5 is provided in the semiconductor substrate 1, said trench having a dielectric layer 4, for example made of aluminum oxide, in the lower region. Situated in the semiconductor substrate 1 is a buried first conductive capacitor electrode 1a, which is a doped region.

An insulation collar 3a, for example made of silicon oxide, is provided in the upper region of the trench 5, which insulation collar has been produced by means of a deposition and by means of a subsequent spacer etching in the present example. A second conductive capacitor electrode is situated in the trench 5, which electrode has a lower part 10 made of polysilicon and an upper part 30a made of titanium, which has been deposited directly above the lower part 10 and etched back.

The known arrangement outlined with reference to FIG. 2 has the disadvantage that it has a Schottky contact between the lower part 10 made of silicon and the upper part 30a made of titanium of the second conductive capacitor electrode.

Therefore, it is an object of the present invention to provide an improved trench capacitor and a corresponding fabrication method which avoid the formation of a Schottky contact in the second conductive capacitor electrode and thus furnish a reduced contact resistance.

According to the invention, this object is achieved by means of the trench capacitor having an insulation collar which is specified in claim 1. Furthermore, this object is achieved by means of the fabrication method specified in claim 6.

The respective subclaims relate to preferred developments.

The idea on which the present invention is based is to produce a contact part made of a metal silicide between the lower part made of silicon and the upper part made of metal of the second conductive capacitor electrode, with the result that the contact resistance is drastically reduced.

In accordance with one preferred development, the part made of the metal silicide is located in the region between the insulation collar.

In accordance with a further preferred development, the first conductive capacitor electrode is a region of increased doping in the semiconductor substrate.

In accordance with a further preferred development, the lower nonmetallic part comprises silicon, the upper metallic part comprises titanium, cobalt or nickel or a compound of one or more of said metals, and the part made of the metal silicide comprises titanium silicide, cobalt silicide or nickel silicide.

In accordance with a further preferred development, the dielectric layer comprises Al₂O₃.

In accordance with a further preferred development, the lower nonmetallic part is provided from silicon and the part made of the metal silicide is provided in a thermal process in a self-aligning manner from a top side region of the nonmetallic part and a metallic layer provided above the latter.

In accordance with a further preferred development, the thermal process has a first and a second stage and, before the first stage, a metal nitride layer is provided above the metal layer, then the first stage is effected, afterward the metal nitride layer and a non-silicided part of the metal layer are removed, and finally the second stage is effected.

In accordance with a further preferred development the metal layer is a titanium layer and the metal nitride layer is a titanium nitride layer and a C49 phase is formed from TiSi₂ in the first stage and a C54 phase is formed from TiSi₂ in the second stage.

In accordance with a further preferred development, the upper metallic part is provided from titanium, cobalt or nickel or a compound of one or more of said metals.

An exemplary embodiment of the present invention is illustrated in the drawings and explained in more detail in the description below.

In the figures:

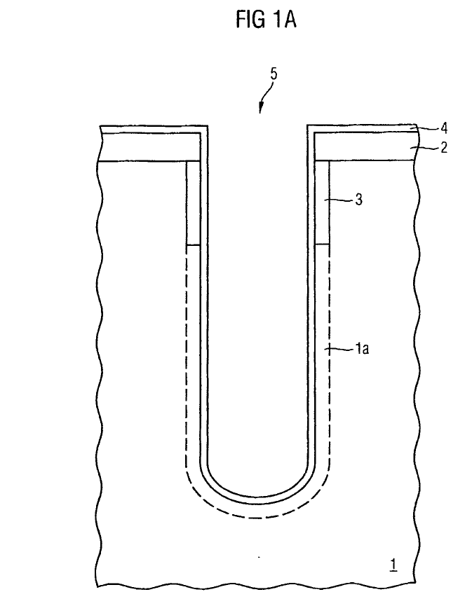

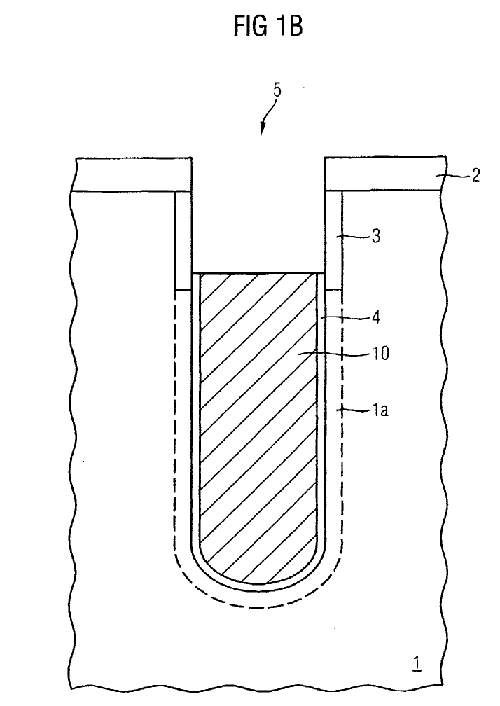

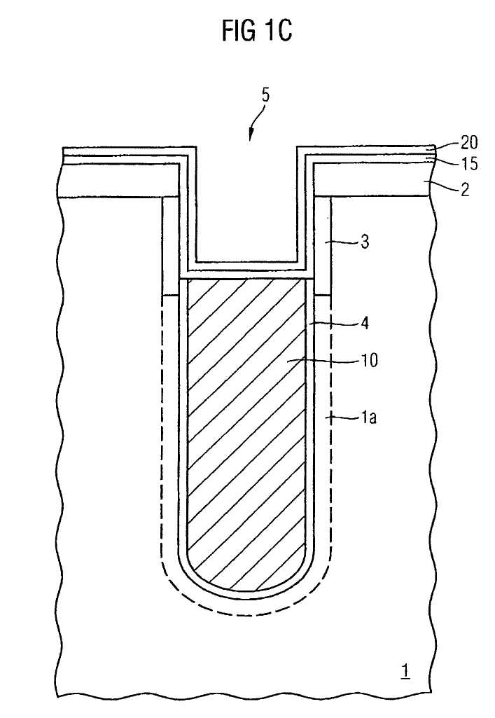

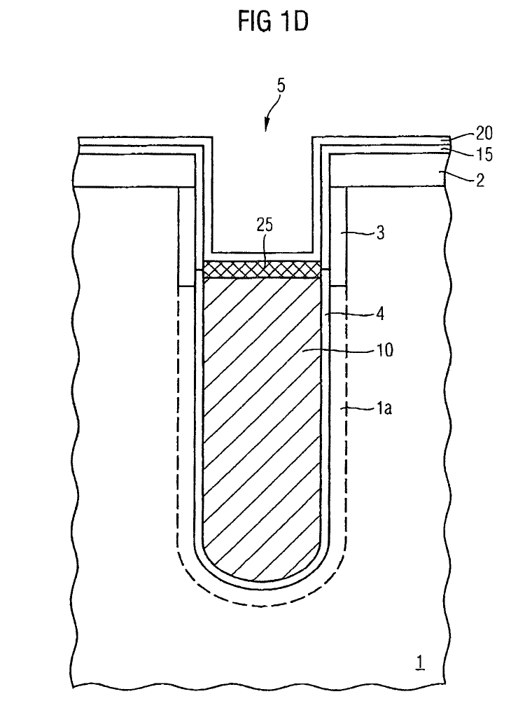

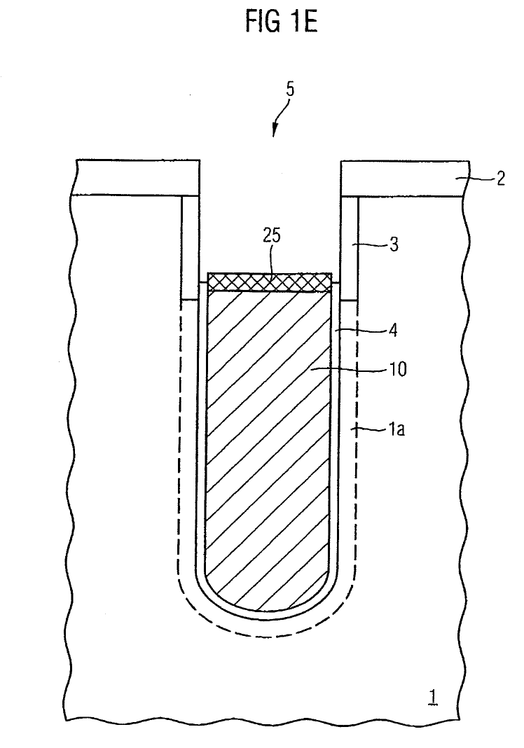

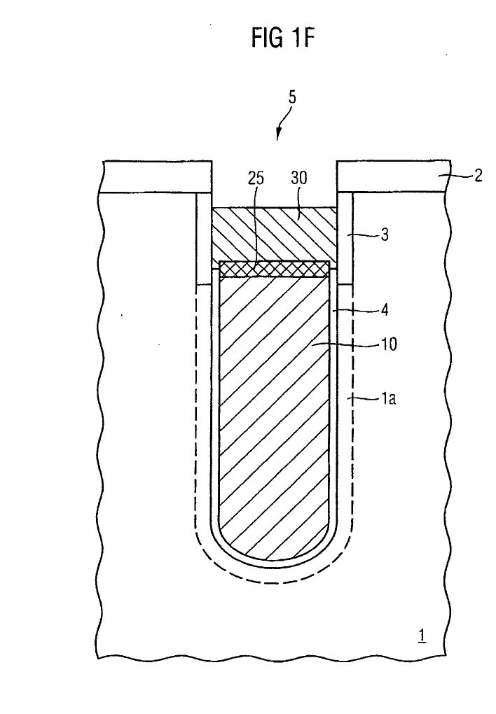

FIGS. 1a-f show the method steps essential to understanding the invention for fabricating an exemplary embodiment of the trench capacitor according to the invention; and

FIG. 2 shows a trench capacitor disclosed in DE 101 28 718 A1.

In the figures, identical reference symbols designate identical or functionally identical component parts.

FIGS. 1a-f show the method steps essential to understanding the invention for fabricating an exemplary embodiment of the trench capacitor according to the invention.

In accordance with FIG. 1a, a trench 5 has been produced in a silicon semiconductor substrate 1 by means of a pad nitride layer 2 as mask and an insulation collar 3 made of silicon oxide has subsequently been produced in the upper region in the semiconductor substrate 1. A buried first conductive capacitor plate la of the trench capacitor is furthermore provided in the semiconductor substrate 1. In order to attain the process state shown in FIG. 1a, a dielectric layer 4 made of aluminum oxide (Al₂O₃) has been deposited above the structure.

Referring further to FIG. 1b, afterward a polysilicon layer is deposited and the polysilicon is etched back in order to form the lower part 10 of the second conductive capacitor electrode and the dielectric layer 4 made of aluminum oxide is subsequently removed selectively in the upper uncovered region.

As illustrated in FIG. 1c, a titanium layer 15 is then deposited above the resulting structure and a titanium nitride layer 20 is deposited above said titanium layer. The deposition is typically effected by means of a PVD, CVD or ALD process with a thickness of typically 5 nm or less.

This is followed by, as in FIG. 1d, a thermal process with a first heat treatment step, in which silicon of the polysilicon layer 10 reacts with the overlying titanium of the titanium layer 15 to form titanium silicide TiSi₂ in the C49 phase and forms an intermediate region 25. In this case, no reaction occurs between titanium and titanium nitride or titanium and silicon oxide or silicon nitride. Afterward, as shown in FIG. 1e, firstly the titanium nitride layer 20 and then the residual titanium of the titanium layer 15 are removed by means of an etching process. A second heat treatment step is subsequently effected, during which the titanium silicide region 25 is converted into the C54 phase.

As is illustrated by the process step in FIG. 1f, afterward the upper region of the trench is filled with a metallic layer 30, for example made of titanium or titanium nitride, and this layer 30 is etched back.

This completes the second conductive capacitor electrode in the trench, which has the lower part 10 made of polysilicon, the intermediate part 25 made of titanium silicide (TiSi₂) and the upper part 30 made of metallic titanium nitride.

Further process steps, for example steps for connecting the second conductive capacitor electrode to the semiconductor substrate 1 after partial removal of the insulation collar 3 and, if appropriate, formation of transistors to be connected thereto, are well known in the prior art of semiconductor devices having trench capacitors and are not explained any further here.

Although the present invention has been described above on the basis of a preferred exemplary embodiment, it is not restricted thereto, but rather can be modified in diverse ways.

In particular, the materials cited are only by way of example and can be replaced by other materials having suitable properties. The same applies to the etching processes and deposition processes mentioned.

Although the insulation collar 3 has been provided in a manner integrated in the semiconductor substrate 1 in the above example, the present invention can also be applied, of course, to trench capacitors in which the insulation collar is formed in the trench on the semiconductor substrate.

Moreover, the example for the metal silicide region 25 is not restrictive, and instead of titanium it is also possible to use cobalt or nickel or similar metals which form, in a thermal process, a silicide having a sufficiently low contact resistance.

List of Reference Symbols

1 Silicon semiconductor substrate
1a Buried capacitor electrode
5 Trench
2 Pad nitride layer
3, 3a Insulation collar
4 Dielectric layer made of Al₂O₃
15 Metal layer
20 Metal nitride layer
25 Metal silicide layer
30, 30a Metal layer

1. Trench capacitor, in particular for use in a semiconductor memory cell, having:
a trench (5) formed in a semiconductor substrate (1);
an insulation collar (3) in the upper region of the trench (5);
a first conductive capacitor electrode (1a) situated in the trench (5) or in the semiconductor substrate (1);
a conductive second capacitor electrode (10, 25, 30), situated in the trench (5), has a lower nonmetallic part (10) and an upper metallic part (30), the upper metallic part (30) extending right into the region between the insulation collar (3);
a dielectric layer (4) as capacitor dielectric situated between the first and second capacitor electrodes (la; 10, 25, 30);
characterized
in that
a part (25) made of a metal silicide is situated between the lower nonmetallic part (10) and the upper metallic part (30):

2. Trench capacitor according to claim 1,
characterized
in that the part (25) made of the metal silicide is situated in the region between the insulation collar (3).

3. Trench capacitor according to claim 1,
characterized
in that the first conductive capacitor electrode (la) is a region of increased doping in the semiconductor substrate (1).

4. Trench capacitor according to claim 1,
characterized
in that the lower nonmetallic part (10) comprises silicon, the upper metallic part (30) comprises titanium, cobalt or nickel or a compound of one or more of said metals, and the part (25) made of the metal silicide comprises titanium silicide, cobalt silicide or nickel silicide.

5. Trench capacitor according to claim 1,
characterized
in that the dielectric layer (4) comprises Al₂O₃.

6. Fabrication method for a trench capacitor, in particular for use in a semiconductor memory cell, having the following steps:
provision of a trench (5) in a semiconductor substrate (1);
provision of an insulation collar (3) in the upper region of the trench (5);
provision of a first conductive capacitor electrode (1a) situated in the trench (5) or in the semiconductor substrate (1);
provision of a conductive second capacitor electrode (10, 25, 30) situated in the trench (5), which electrode has a lower nonmetallic part (10) and an upper metallic part (30), the upper metallic part (30) extending right into the region between the insulation collar (3);
provision of a dielectric layer (4) as capacitor dielectric situated between the first and second capacitor electrodes (1a; 10, 25, 30);
characterized
in that
a part (25) made of a metal silicide is provided between the lower nonmetallic part (10) and the upper metallic part (30).

7. Method according to claim 6,
characterized
in that the lower nonmetallic part (10) is provided from silicon and the part (25) made of the metal silicide is provided in a thermal process in a self-aligning manner from a top side region of the nonmetallic part (10) and a metallic layer (15) provided above the latter.

8. Method according to claim 7,
characterized
in that the thermal process has a first and a second stage and, before the first stage, a metal nitride layer (20) is provided above the metal layer (15), then the first stage is effected, afterward the metal nitride layer (20) and a non-silicided part of the metal layer (15) are removed, and finally the second stage is effected.

9. Method according to claim 8,
characterized
in that the metal layer (15) is a titanium layer and the metal nitride layer (20) is a titanium nitride layer and a C49 phase is formed from TiSi₂ in the first stage and a C54 phase is formed from TiSi₂ in the second stage.

10. Method according to claim 6,
characterized
in that the upper metallic part (30) is provided from titanium, cobalt or nickel or a compound of one or more of said metals.
